(19) United States
(12) Patent Application Publication
(10) Pub. No.: US 2025/0380400 A1
(43) Pub. Date: Dec. 11, 2025

(54) FABRICATION METHOD FOR SEMICONDUCTOR STRUCTURE AND SEMICONDUCTOR STRUCTURE

(71) Applicant: CXMT Corporation, Hefei City (CN)

(72) Inventors: Shaoyou XIONG, Hefei City (CN); SHIJIE BAI, Hefei City (CN)

(73) Assignee: CXMT Corporation, Hefei City (CN)

(21) Appl. No.: 19/238,581

(22) Filed: Jun. 16, 2025

Related U.S. Application Data
(63) Continuation of application No. PCT/CN2025/082242, filed on Mar. 13, 2025.

(30) Foreign Application Priority Data
Jun. 6, 2024 (CN) 202410732590.0

(51) Int. Cl. H10B 12/00; H10D 30/01; H10D 30/63; H10D 64/27

(52) U.S. Cl. CPC H10B 12/31; H10B 12/0385; H10B 12/05; H10B 12/488; H10D 30/025; H10D 30/63; H10D 64/514

(57) ABSTRACT

A fabrication method for a semiconductor structure. The method includes a substrate, the substrate has active pillars disposed at intervals in both a first direction and a second direction, the first direction is perpendicular to the second direction, first dielectric layers exist among the active pillars, and the first dielectric layers are at least flush with the active pillars; word line structures are formed, the word line structures surround the active pillars and extend in the first direction, and multiple ones of the word line structures are disposed at intervals in the second direction; at least a part of the first dielectric layers are removed to form first openings; contact structures are formed, where the contact structures at least partially fill the first openings; and capacitor structures are formed, where the capacitor structures are electrically connected to the contact structures.

### CROSS-REFERENCE TO RELATED APPLICATIONS

This application is a continuation of International Patent Application No. PCT/CN2025/082242 filed on Mar. 13, 2025, which claims priority to Chinese Patent Application No. 202410732590.0 filed on Jun. 6, 2024. The disclosures of the above-referenced applications are hereby incorporated by reference in their entirety.

### BACKGROUND

A dynamic random access memory (DRAM) is a semiconductor memory. Compared with a static memory, the DRAM has advantages of relatively simple structure, relatively low fabricating costs, and relatively high capacity density. With the development of the semiconductor industry, a semiconductor device is becoming highly integrated, that is, miniaturized. The highly integrated semiconductor device is being converted from a planar channel transistor to a vertical channel transistor (VCT).

However, in the fabrication procedure of the vertical channel transistor, there is still a case in which the fabrication process of a semiconductor memory device is relatively complex and the yield is relatively low. How to increase the yield of the semiconductor memory device and simplify the fabrication process of the semiconductor memory device is an urgent technical problem to be resolved currently.

### SUMMARY

Embodiments of the present disclosure relate to the field of semiconductor technologies, and in particular, to a fabrication method for a semiconductor structure and a semiconductor structure.

Embodiments of the present disclosure provide a fabrication method for a semiconductor structure and a semiconductor structure, which at least helps increase the yield of a semiconductor memory device and simplify the fabrication process of the semiconductor memory device.

According to some embodiments of the present disclosure, in an aspect of the embodiments of the present disclosure, a fabrication method for a semiconductor structure is provided, including the steps as follows.

A substrate is provided, where the substrate has active pillars disposed at intervals in both a first direction and a second direction, both the first direction and the second direction are parallel to the surface of the substrate, the first direction is perpendicular to the second direction, first dielectric layers exist among the active pillars, and the first dielectric layers are flush with at least the active pillars;
word line structures are formed, where the word line structures surround the active pillars and extend in the first direction, and multiple ones of the word line structures are disposed at intervals in the second direction;
at least a part of the first dielectric layers are removed to form first openings;
contact structures are formed, where the contact structures at least partially fill the first openings; and
capacitor structures are formed, where the capacitor structures are electrically connected to the contact structures.

According to some embodiments of the present disclosure, in another aspect of the embodiments of the present disclosure, a semiconductor structure is further provided, including:
a substrate, where the substrate has active pillars disposed at intervals in both a first direction and a second direction, both the first direction and the second direction are parallel to the surface of the substrate, the first direction is perpendicular to the second direction, first dielectric layers exist among the active pillars, and the first dielectric layers are flush with at least the active pillars;
word line structures, where the word line structures surround the active pillars and extend in the first direction, and multiple ones of the word line structures are disposed at intervals in the second direction;
contact structures, where the contact structures are electrically connected to at least the active pillars; and
capacitor structures, where the capacitor structures are electrically connected to the contact structures.

The embodiments of the present disclosure provide the fabrication method for a semiconductor structure and the semiconductor structure. At least a part of first dielectric layers is removed to form first openings, top sizes of the first openings are larger than bottom sizes thereof, contact structures are formed in the first openings, and the contact structures are electrically connected to capacitor structures. In this way, a process of forming the contact structures is simplified, and the contact structures relatively greatly increase a contact window, thereby improving the yield of the semiconductor structure.

### BRIEF DESCRIPTION OF DRAWINGS

One or more embodiments are exemplified with the figures in the accompanying drawings corresponding to the one or more embodiments. These example descriptions are not intended to limit the embodiments, and unless specifically stated, no scale limitations are constituted by the figures in the accompanying drawings. To describe the technical solutions in the embodiments of the present disclosure or the conventional technologies more clearly, the accompanying drawings required by the embodiments are briefly described below. Clearly, the accompanying drawings in the following description show merely some embodiments of the present disclosure, and other drawings may be obtained by a person of ordinary skill in the art from these accompanying drawings without creative efforts.

FIG. 1 schematically shows a fabrication method for a semiconductor structure and a top view of a substrate of a semiconductor structure according to the present disclosure;

FIG. 2A is a first process flowchart of a specific implementation of a method for forming a semiconductor structure according to the present disclosure;

FIG. 2B is a second process flowchart of a specific implementation of a method for forming a semiconductor structure according to the present disclosure;

FIG. 2C is a third process flowchart of a specific implementation of a method for forming a semiconductor structure according to the present disclosure;

FIG. 2D is a fourth process flowchart of a specific implementation of a method for forming a semiconductor structure according to the present disclosure;

FIG. 2E is a fifth process flowchart of a specific implementation of a method for forming a semiconductor structure according to the present disclosure;

FIG. 2F is a sixth process flowchart of a specific implementation of a method for forming a semiconductor structure according to the present disclosure;

FIG. 2G is a seventh process flowchart of a specific implementation of a method for forming a semiconductor structure according to the present disclosure;

FIG. 3A is a first process flowchart of another specific implementation of a method for forming a semiconductor structure according to the present disclosure;

FIG. 3B is a second process flowchart of another specific implementation of a method for forming a semiconductor structure according to the present disclosure;

FIG. 3C is a third process flowchart of another specific implementation of a method for forming a semiconductor structure according to the present disclosure;

FIG. 3D is a fourth process flowchart of another specific implementation of a method for forming a semiconductor structure according to the present disclosure;

FIG. 3E is a fifth process flowchart of another specific implementation of a method for forming a semiconductor structure according to the present disclosure;

FIG. 3F is a sixth process flowchart of another specific implementation of a method for forming a semiconductor structure according to the present disclosure;

FIG. 3G is a seventh process flowchart of another specific implementation of a method for forming a semiconductor structure according to the present disclosure;

FIG. 4A is a first process flowchart of still another specific implementation of a method for forming a semiconductor structure according to the present disclosure;

FIG. 4B is a second process flowchart of still another specific implementation of a method for forming a semiconductor structure according to the present disclosure;

FIG. 4C is a third process flowchart of still another specific implementation of a method for forming a semiconductor structure according to the present disclosure;

FIG. 4D is a fourth process flowchart of still another specific implementation of a method for forming a semiconductor structure according to the present disclosure;

FIG. 4E is a fifth process flowchart of still another specific implementation of a method for forming a semiconductor structure according to the present disclosure;

FIG. 4F is a sixth process flowchart of still another specific implementation of a method for forming a semiconductor structure according to the present disclosure;

FIG. 5A is a first process flowchart of yet another specific implementation of a method for forming a semiconductor structure according to the present disclosure;

FIG. 5B is a second process flowchart of yet another specific implementation of a method for forming a semiconductor structure according to the present disclosure;

FIG. 5C is a third process flowchart of yet another specific implementation of a method for forming a semiconductor structure according to the present disclosure;

FIG. 5D is a fourth process flowchart of yet another specific implementation of a method for forming a semiconductor structure according to the present disclosure;

FIG. 5E is a fifth process flowchart of yet another specific implementation of a method for forming a semiconductor structure according to the present disclosure;

FIG. 5F is a sixth process flowchart of yet another specific implementation of a method for forming a semiconductor structure according to the present disclosure;

FIG. 5G is a seventh process flowchart of yet another specific implementation of a method for forming a semiconductor structure according to the present disclosure;

FIG. 5H is an eighth process flowchart of yet another specific implementation of a method for forming a semiconductor structure according to the present disclosure;

FIG. 6A shows an energy dispersive spectrum of initial contact structures according to a specific embodiment of the present disclosure;

FIG. 6B is a schematic structural diagram of a specific implementation of a semiconductor structure according to the present disclosure;

FIG. 7A is a transmission electron microscope diagram of contact structures according to a specific embodiment of the present disclosure;

FIG. 7B is a schematic structural diagram of another specific implementation of a semiconductor structure according to the present disclosure; and

FIG. 8 is a schematic structural diagram of still another specific implementation of a semiconductor structure according to the present disclosure.

### DETAILED DESCRIPTION

It may be learned from the background that in the fabrication procedure of a vertical channel transistor, there is still a case in which the fabrication process of a semiconductor memory device is relatively complex and the yield is relatively low. How to increase the yield of the semiconductor memory device and simplify the fabrication process of the semiconductor memory device is an urgent technical problem to be currently resolved.

Embodiments of the present disclosure provide a fabrication method for a semiconductor structure and a semiconductor structure. At least a part of first dielectric layers is removed to form first openings, top sizes of the first openings are larger than bottom sizes thereof, contact structures are formed in the first openings, and the contact structures are electrically connected to capacitor structures. In this way, a process of forming the contact structures is simplified, and the contact structures relatively greatly increase a contact window, thereby improving the yield of the semiconductor structure.

The embodiments of the present disclosure are described in detail below with reference to the accompanying drawings. However, it may be understood by a person of ordinary skill in the art that in the embodiments of the present disclosure, many technical details are provided to enable readers to better understand the present disclosure. However, the technical solutions claimed in the present disclosure may be implemented even without these technical details and various variations and modifications made based on the following embodiments.

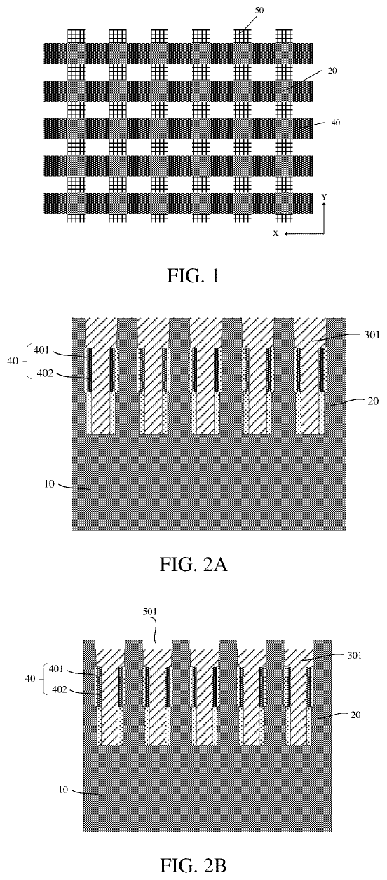

FIG. 1 schematically shows a fabrication method for a semiconductor structure and a top view of a substrate of a semiconductor structure according to the present disclosure.

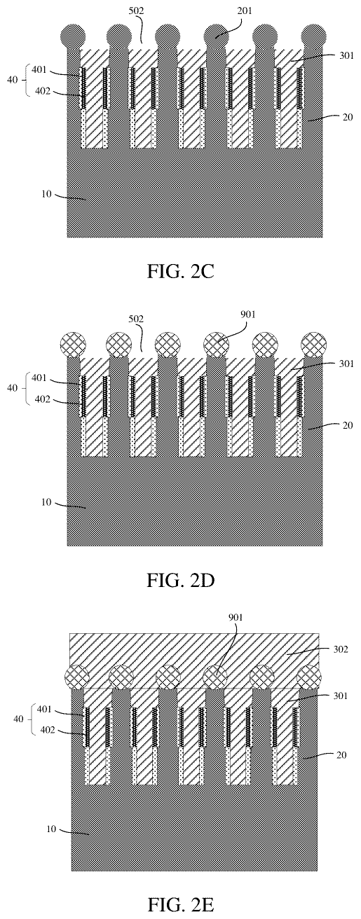

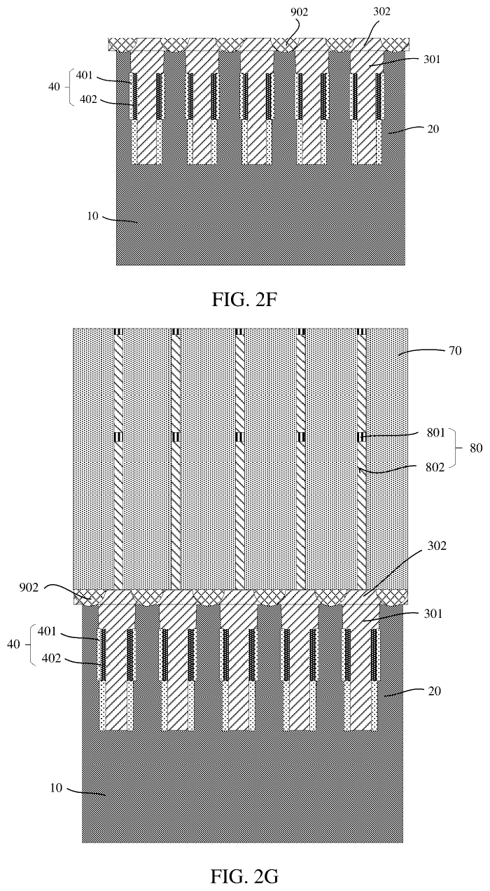

FIG. 2A to FIG. 2G are process flowcharts of a specific implementation of a method for forming a semiconductor structure according to the present disclosure.

Referring to FIG. 1 and FIG. 2A, the fabrication method for a semiconductor structure includes the steps as follows. A substrate 10 is provided, where the substrate 10 has active pillars 20 disposed at intervals in both a first direction X and a second direction Y, both the first direction X and the second direction Y are parallel to the surface of the substrate 10, the first direction X is perpendicular to the second direction Y, first dielectric layers 301 exist among the active pillars 20, and the first dielectric layers 301 are flush with at least the active pillars 20.

The substrate further includes word line structures 40, the word line structures 40 surround the active pillars 20 and extend in the first direction X, and multiple ones of the word line structures 40 are disposed at intervals in the second direction Y; and the word line structures 40 further include word line isolation layers 401 and word line metal layers 402.

Then, as shown in FIG. 2B, a part of the first dielectric layers 301 are removed to form first openings 501, and a method for removing the first dielectric layers 301 includes dry etching; and sidewalls of the first openings 501 expose a part of the active pillars 20, and bottoms of the first openings 501 expose a part of the first dielectric layers 301.

Then, as shown in FIG. 2C and FIG. 2D, contact structures 901 are formed, and the contact structures 901 at least partially fill the first openings 501. That is, the contact structures 901 do not fill the first openings 501, and the contact structures 901 partially occupy the space of the first openings 501. Before the contact structures 901 are formed, the method further includes the step as follows. A first treatment process is performed on the part of the active pillars 20 exposed on the sidewalls of the first openings 501 to expand the exposed part of the active pillars 20 to form active pillar protrusion portions 201. The first treatment process may be an epitaxial (EPI) treatment process. The material of the active pillars 20 may be silicon (Si), germanium (Ge), silicon germanium (GeSi), or the like, which may be specifically selected according to a requirement. When being silicon, the material of the active pillars 20 may be monocrystalline silicon or polycrystalline silicon. By adopting the epitaxial treatment process, the active pillars 20 exposed on the sidewalls of the first openings may epitaxially grow. Specifically, as shown in FIG. 2C, the sizes of the active pillar protrusion portions 201 formed after the epitaxial treatment have a tendency to first increase and then decrease from top to bottom. Specifically, the active pillar protrusion portions 201 may be spherical, elliptical or fusiform in shape, and a spherical shape is taken as an example in FIG. 2C. Then, as shown in FIG. 2D, a second treatment process is performed on the active pillar protrusion portions 201 to form initial contact structures 901. The second treatment process further includes first depositing cobalt, nickel, or cobalt-nickel alloy on the active pillar protrusion portions 201, and then performing heat treatment, so that the active pillar protrusion portions 201 react with cobalt, nickel, or cobalt-nickel alloy to form the initial contact structures 901. The materials of the initial contact structures 901 may be cobalt silicide, nickel silicide, or cobalt nickel silicide. The sizes of the initial contact structures 901 have a tendency to first increase and then decrease from top to bottom. Specifically, the initial contact structures 901 may be spherical, elliptical or fusiform in shape, and a spherical shape is taken as an example in FIG. 2D. A second opening 502 is formed between adjacent ones of the initial contact structures 901. Because the initial contact structures 901 do not fill the first openings 501, the initial contact structures 901 occupy some space of the first openings 501. An unoccupied section of each of the first openings 501 forms the second opening 502.

Then, as shown in FIG. 2E, a second dielectric layer 302 is formed, and the second dielectric layer 302 fills the second opening 502 and covers the initial contact structures 901. Then, as shown in FIG. 2F, a part of the second dielectric layer 302 and a part of the initial contact structures 901 are removed, so that the initial contact structures 901 are exposed. Then, a part of the second dielectric layer 302 and a part of the initial contact structures 901 are further removed, so that a remaining part of the initial contact structures 901 form contact structures 902. Top sizes of the contact structures 902 are larger than bottom sizes of the contact structures 902. The top sizes of the contact structures 902 are larger than the bottom sizes thereof, so that the contact structures 902 can provide a relatively large contact area, thereby further improving the yield and the performance of the semiconductor structure.

Then, as shown in FIG. 2G, capacitor structures 70 are formed on the contact structures 902, and the capacitor structures 70 are electrically connected to the contact structures 902. FIG. 2G schematically shows capacitor structures 70. Specifically, each of the capacitor structures 70 may be a double-sided capacitor or a single-sided cylindrical capacitor. Each of the capacitor structures 70 may include a top electrode, a bottom electrode, and a dielectric layer. A support structure 80 may be further included between the capacitor structures 70, and the support structure 80 includes a first support structure 801 and a second support structure 802.

According to the foregoing method, a vertical channel transistor (VCT) may be formed, and the contact structures 901 serving as capacitor contact structures are enabled to provide a relatively large contact area, so that the yield and the performance of the semiconductor structure are improved.

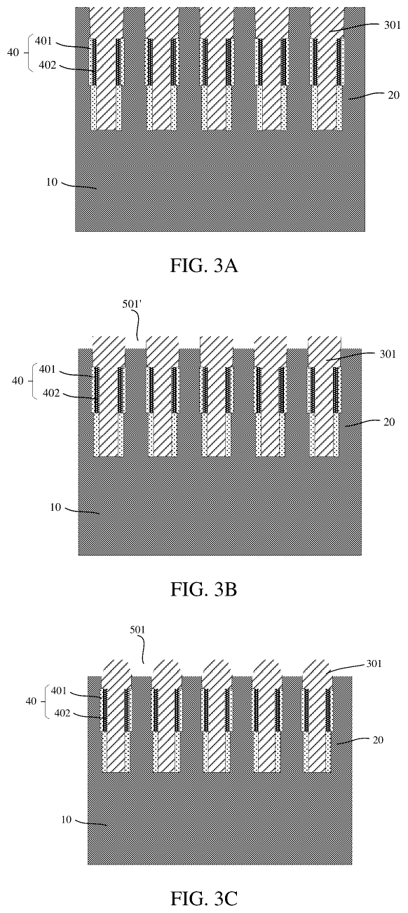

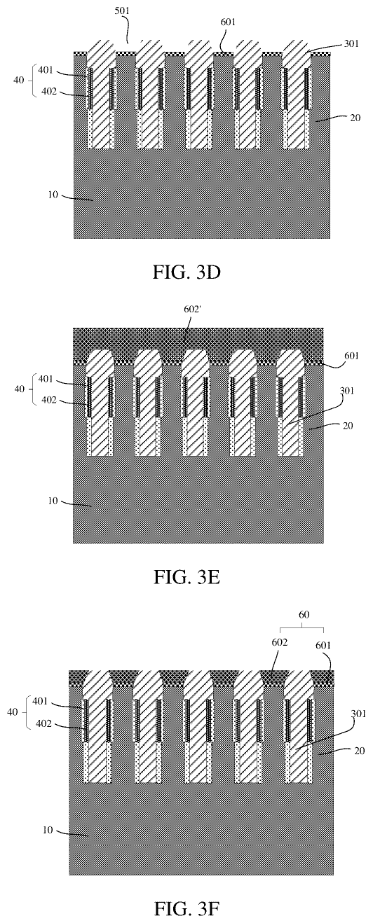

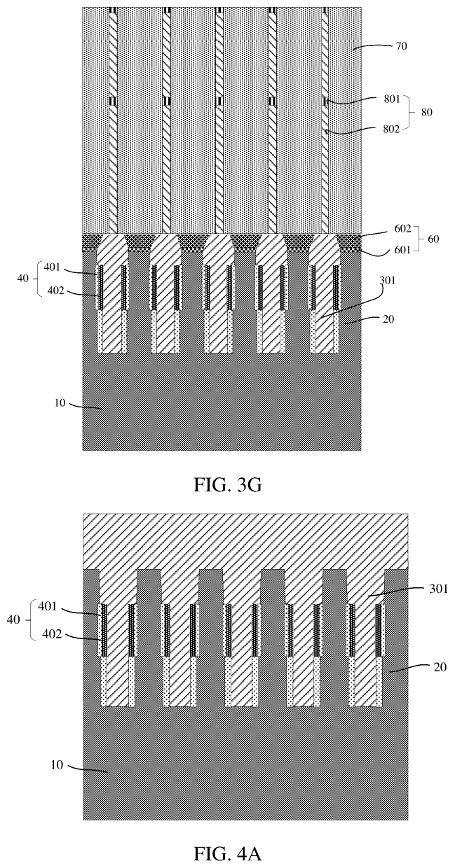

FIG. 3A to FIG. 3G are process flowcharts of another specific implementation of a method for forming a semiconductor structure according to the present disclosure.

In the foregoing embodiment, the active pillar protrusion portions are formed by epitaxy, and the second treatment process is performed on the active pillar protrusion portions, so that the initial contact structures are formed by the active pillar protrusion portions. After further etching, the remaining part of the initial contact structures serve as the contact structures. The top sizes of the contact structures are larger than the bottom sizes thereof, so that contact areas of the contact structures increase, thereby further improving the yield and the performance of the semiconductor structure. However, an epitaxial growth procedure is relatively slow, and a process is relatively complex. In the following embodiments, a method with a simpler process procedure and a shorter process time is to be specifically described.

With reference to FIG. 1 and FIG. 3A, a substrate 10 is provided, where the substrate 10 has active pillars 20 disposed at intervals in both a first direction X and a second direction Y, both the first direction X and the second direction Y are parallel to a surface of the substrate 10, the first direction X is perpendicular to the second direction Y, first dielectric layers 301 exist among the active pillars 20, and the first dielectric layers 301 are flush with the active pillars 20.

The substrate 10 further includes word line structures 40, the word line structures 40 surround the active pillars 20 and extend in the first direction X, and the word line structures 40 are disposed at intervals in the second direction Y; and the word line structures 40 further include word line isolation layers 401 and word line metal layers 402.

Then, as shown in FIG. 3B and FIG. 3C, a part of the first dielectric layers 301 and a part of the active pillars 20 are removed to form first openings 501, sidewalls of the first openings 501 expose a part of the first dielectric layers 301, and bottoms of the first openings 501 expose the part of the active pillars 20.

Specifically, as shown in FIG. 3B, a part of the active pillars 20 are removed by adopting a first etching process, to form first initial openings 501′, sidewalls of the first initial openings 501′ expose a part of the first dielectric layers 301, and bottoms of the first initial openings 501′ expose a part of the active pillars 20. The first etching process may be specifically a dry etching process, and a specific etching gas may be carbon tetrafluoride (CF4).

Specifically, as shown in FIG. 3C, a second etching process is adopted to continue etching on the basis of the first initial openings, etching continues at the bottoms thereof to remove a part of the active pillars 20, and etching continues at the sidewalls of the first initial openings 501′ to remove a part of the dielectric layers 301 to form the first openings 501. The depths of the first openings 501 are greater than the depths of the first initial openings 501′, and top sizes of the first openings 501 are larger than bottom sizes of the first openings 501. The second etching process may be a dry etching process, and an etching gas may be a mixture of carbon tetrafluoride (CF4) and trifluoromethane (CHF3). By adopting the second etching process, etching continues at the bottoms of the first initial openings 501′ and the sidewalls thereof are to be expanded. In a specific embodiment, the second etching process enables each of the first initial openings 501′ to be expanded at each of the left and right sides by at least 3 nm. In other words, there is a size difference between the top sizes of the first openings 501 and the bottom sizes of the first openings 501, and the size difference is not less than 6 nm.

By adopting the first etching process and the second etching process, the top sizes of the first openings 501 are relatively large, which provides convenience for subsequently filling and forming the contact structures, so that the subsequent contact structures are easier to fill and the device structure is prevented from being affected due to bubbles formed in the contact structures. In addition, relatively large top sizes of the first openings 501 also make the top sizes of the subsequently formed contact structures relatively large, so that the contact areas increase, thereby further improving the yield and the performance of the semiconductor structure.

Then, as shown in FIG. 3D to FIG. 3F, contact structures 60 are formed, where the contact structures 60 fill the first openings 501; the contact structures include first metal layers 601 and second metal layers 602, and the first metal layers 601 cover the bottoms of the first openings 501; and the second metal layers 602 fill the first openings 501. Specifically, as shown in FIG. 3D, the first metal layers 601 are first formed at the bottoms of the first openings 501, and the first metal layers 601 cover the bottoms of the first openings 501 and do not fill the first openings 501. Then, as shown in FIG. 3E, second initial metal layers 602′ are formed, and the second initial metal layers 602′ fill the first openings 501 and cover the first dielectric layers 301. Then, as shown in FIG. 3F, a part of the second initial metal layers 602′ are removed, so that a remaining part of the second initial metal layers 602′ serve as the second metal layers 602, and the second metal layers 602 are flush with the first dielectric layers.

The material of the first dielectric layers 301 may be silicon nitride, silicon oxynitride, silicon carbide nitride, or the like. Because there is an etching selectivity ratio between the first dielectric layers 301 and the active pillars 20, a part of the active pillars 20 are removed in a first etching process procedure, and in a second etching process procedure, a part of the active pillars 20 are continuously removed, and expansion is performed to remove a part of the first dielectric layers 301 to form the first openings 501. The contact structures 60 are formed in the first openings 501. Because a procedure of forming the first openings 501 and a procedure of filling the first openings 501 are relatively easy to control and process procedures are simple, the entire procedure of forming the semiconductor structure is simplified and a process time is shortened.

Then, as shown in FIG. 3G, capacitor structures 70 are formed, and the capacitor structures 70 are electrically connected to the contact structures 60. FIG. 3G schematically shows capacitor structures 70. Specifically, each of the capacitor structures 70 may be a double-sided capacitor or a single-sided cylindrical capacitor. Each of the capacitor structures 70 may include a top electrode (not shown in the figure), a bottom electrode (not shown in the figure), and a dielectric layer (not shown in the figure). A support structure 80 may be further included between the capacitor structures 70, and the support structure 80 includes a first support structure 801 and a second support structure 802.

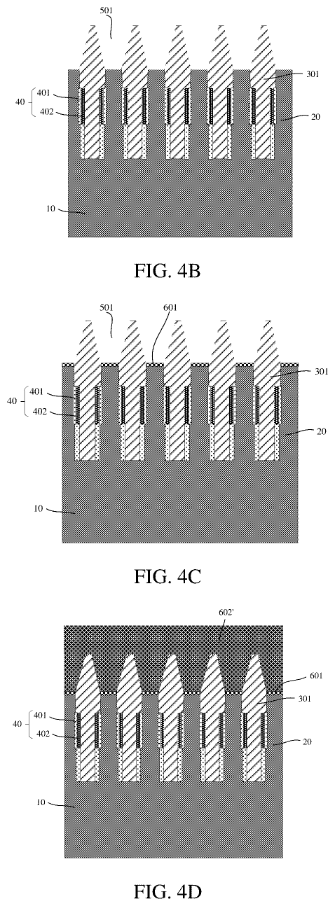

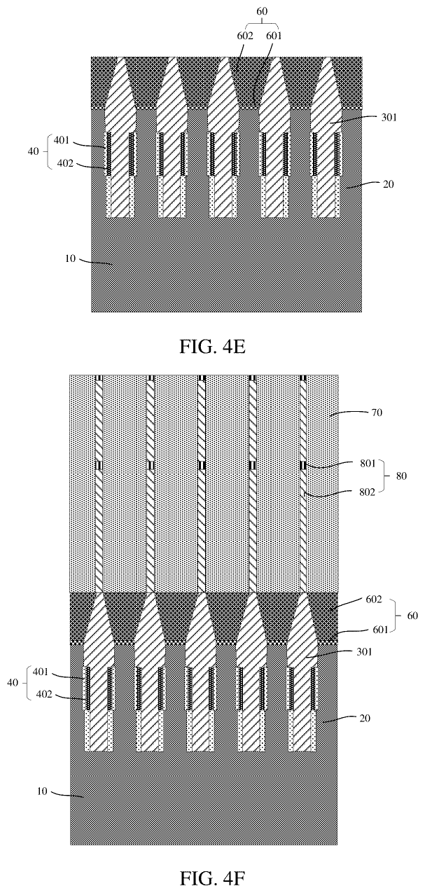

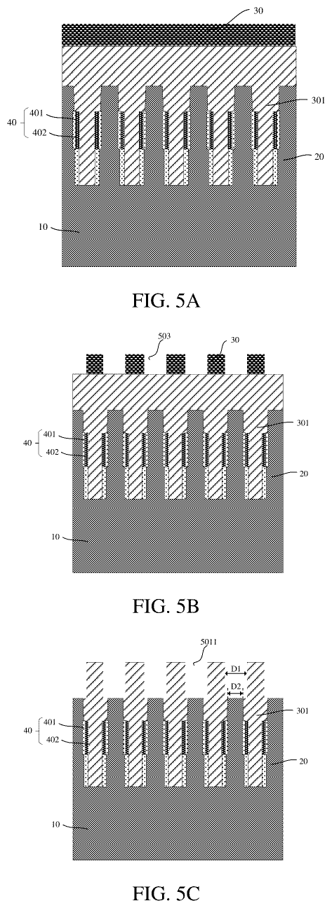

FIG. 4A to FIG. 4F are process flowcharts of still another specific implementation of a method for forming a semiconductor structure according to the present disclosure.

As shown in FIG. 4A, different from that in the other embodiments, first dielectric layers 301 are further covered with active pillars 20. With reference to FIG. 1 and FIG. 4A, a substrate 10 is provided, where the substrate 10 has the active pillars 20 disposed at intervals in both a first direction X and a second direction Y, both the first direction X and the second direction Y are parallel to the surface of the substrate 10, the first direction X is perpendicular to the second direction Y, the first dielectric layers 301 exist among the active pillars 20, and the first dielectric layers 301 are covered with the active pillars 20.

As shown in FIG. 4B, a part of the first dielectric layers 301 and a part of the active pillars 20 are removed through etching to form first openings 501. Specifically, a mixed etching gas of carbon tetrafluoride (CF4) and trifluoromethane (CHF3) may be adopted and by controlling an etching angle, for example, first vertically etching for a specific time and then changing an etch bias to form a specific angle, etching continues to form the first openings 501. As shown in FIG. 4A, because the first dielectric layers 301 still exist at the tops of the active pillars, in a procedure of forming the first openings 501 through etching, the depths of the first openings 501 may be deeper, and top sizes of the first openings 501 may be wider, that is, top sizes of subsequently formed contact structures are also larger, so that contact resistance decreases and the performance of a semiconductor device is improved.

Then, as shown in FIG. 4C to FIG. 4E, contact structures 60 are formed, where the contact structures 60 fill the first openings 501; the contact structures include first metal layers 601 and second metal layers 602, and the first metal layers 601 cover the bottoms of the first openings 501; and the second metal layers 602 fill the first openings 501. Specifically, as shown in FIG. 4C, the first metal layers 601 are first formed at the bottoms of the first openings 501, and the first metal layers 601 cover the bottoms of the first openings 501 and do not fill the first openings 501. Then, as shown in FIG. 4D, second initial metal layers 602′ are formed, and the second initial metal layers 602′ fill the first openings 501 and cover the first dielectric layers 301. Then, as shown in FIG. 4E, a part of the second initial metal layers 602′ are removed, so that a remaining part of the second initial metal layers 602′ serve as the second metal layers 602, and the second metal layers 602 are flush with the first dielectric layers.

Then, as shown in FIG. 4F, capacitor structures 70 are formed, and the capacitor structures 70 are electrically connected to the contact structures 60. FIG. 4F schematically shows capacitor structures 70. Specifically, each of the capacitor structures 70 may be a double-sided capacitor or a single-sided cylindrical capacitor. Each of the capacitor structures 70 may include a top electrode (not shown in the figure), a bottom electrode (not shown in the figure), and a dielectric layer (not shown in the figure). A support structure 80 may be further included between the capacitor structures 70, and the support structure 80 includes a first support structure 801 and a second support structure 802.

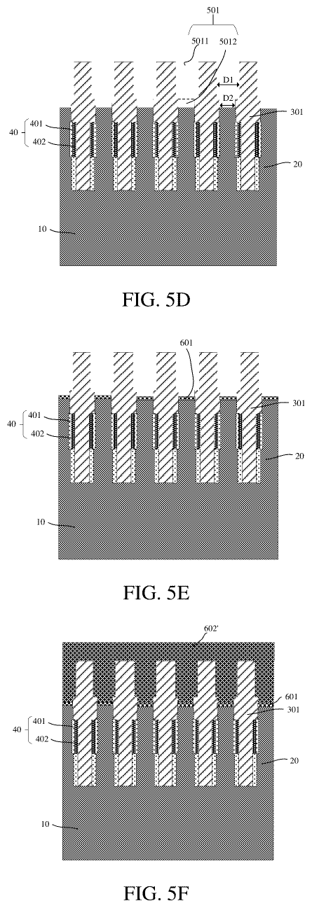

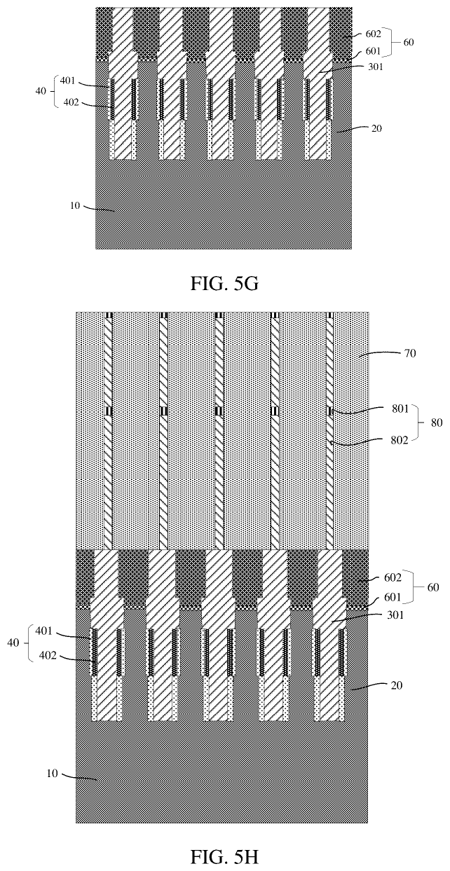

FIG. 5A to FIG. 5H are process flowcharts of yet another specific implementation of a method for forming a semiconductor structure according to the present disclosure.

With reference to FIG. 1 and FIG. 5A, a substrate 10 is provided, where the substrate 10 has active pillars 20 disposed at intervals in both a first direction X and a second direction Y, both the first direction X and the second direction Y are parallel to the surface of the substrate 10, the first direction X is perpendicular to the second direction Y, first dielectric layers 301 exist among the active pillars 20, and the first dielectric layers 301 cover the active pillars 20. Photoresist layers 30 are formed on the active pillars 20.

Then, as shown in FIG. 5B, the photoresist layers 30 are developed to form third openings 503, and the opening sizes of the third openings 503 are larger than top sizes of the active pillars 20.

Then, as shown in FIG. 5C and FIG. 5D, the first dielectric layers 301 are etched with the third openings 503 until the active pillars 20 are exposed to form first initial openings 5011, and a part of the active pillars 20 are continuously etched with the first initial openings 5011 to form second initial openings 5012, where the projections of the second initial openings 5012 on the surface of the substrate 10 are located within the projections of the first initial openings 5011 on the surface of the substrate 10, and the first initial openings 5011 and the second initial openings 5012 jointly constitute the first openings 501. Specifically, as shown in FIG. 5C, the sizes of the first initial openings 5011 are larger than the top sizes of the active pillars 20, and the sizes of the first initial openings 5011 are DI and the top sizes of the active pillars 20 are D2. As shown in FIG. 5D, the part of the active pillars 20 are continuously etched along the first initial openings 5011 to form the second initial openings 5012. A part above a dotted line in FIG. 5D indicates each of the first initial openings 5011, a part below the dotted line indicates each of the second initial openings 5012, and the first initial openings 5011 and the second initial openings 5012 jointly constitute the first openings 501.

Then, as shown in FIG. 5E to FIG. 5G, contact structures 60 are formed, where the contact structures 60 fill the first openings 501; the contact structures include first metal layers 601 and second metal layers 602, and the first metal layers 601 cover the bottoms of the first openings 501; and the second metal layers 602 fill the first openings 501. Specifically, as shown in FIG. 5E, the first metal layers 601 are first formed at the bottoms of the first openings 501, and the first metal layers 601 cover the bottoms of the first openings 501 and do not fill the first openings 501. Then, as shown in FIG. 5F, second initial metal layers 602′ are formed, and the second initial metal layers 602′ fill the first openings 501 and cover the first dielectric layers 301. Then, as shown in FIG. 5G, a part of the second initial metal layers 602′ are removed, so that a remaining part of the second initial metal layers 602′ serve as the second metal layers 602, and the second metal layers 602 are flush with the first dielectric layers. Top sizes of the contact structures 60 are larger than bottom sizes of the contact structures 60, and the top sizes of the contact structures 60 are at least 6 nm larger than the bottom sizes of the contact structures 60. The top sizes are relatively large, which provides convenience for subsequently filling and forming the contact structures, so that the subsequent contact structures are easier to fill and the device structure is prevented from being affected due to bubbles formed in the contact structures. In addition, the top sizes of the contact structures are relatively large, so that the contact areas increase, thereby further improving the yield and the performance of the semiconductor structure.

Then, as shown in FIG. 5H, capacitor structures 70 are formed, and the capacitor structures 70 are electrically connected to the contact structures 60. FIG. 5H schematically shows capacitor structures 70. Specifically, each of the capacitor structures 70 may be a double-sided capacitor or a single-sided cylindrical capacitor. Each of the capacitor structures 70 may include a top electrode (not shown in the figure), a bottom electrode (not shown in the figure), and a dielectric layer (not shown in the figure). A support structure 80 may be further included between the capacitor structures 70, and the support structure 80 includes a first support structure 801 and a second support structure 802.

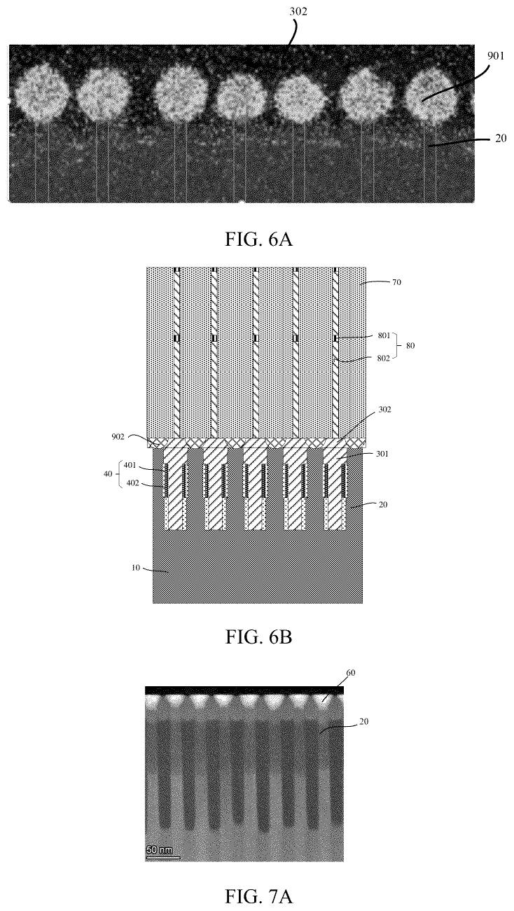

FIG. 6A shows an energy dispersive spectrum (EDS) of initial contact structures according to a specific embodiment of the present disclosure. As shown in FIG. 6A, the sizes of the initial contact structures 901 have a tendency to first increase and then decrease from top to bottom. Specifically, the initial contact structures 901 may be spherical, elliptical or fusiform in shape, and a spherical shape is taken as an example in FIG. 6A. A second dielectric layer 302 is filled between adjacent ones of the initial contact structures 901, and the second dielectric layer 302 further covers the initial contact structures 901.

FIG. 6B is a schematic structural diagram of a specific implementation of a semiconductor structure according to the present disclosure. With reference to FIG. 1 and FIG. 6B, a semiconductor structure in this embodiment of the present disclosure includes a substrate 10, where the substrate 10 has active pillars 20 disposed at intervals in both a first direction X and a second direction Y, both the first direction X and the second direction Y are parallel to the surface of the substrate 10, the first direction X is perpendicular to the second direction Y, first dielectric layers 301 exist among the active pillars 20, and the first dielectric layers 301 are flush with the active pillars 20. Word line structures 40 are further included in the substrate 10, the word line structures 40 surround the active pillars 20 and extend in the first direction X, and multiple ones of the word line structures 40 are disposed at intervals in the second direction Y; and the word line structures 40 further include word line isolation layers 401 and word line metal layers 402. The semiconductor structure in the present disclosure further includes contact structures 902, where the contact structures 902 are electrically connected to the active pillars 20; and further includes capacitor structures 70, where the capacitor structures 70 are electrically connected to the contact structures 902. A support structure 80 may be further included between the capacitor structures 70, and the support structure 80 includes a first support structure 801 and a second support structure 802. There is a size difference between top sizes of the contact structures 902 and bottom sizes of the contact structures 902, the top sizes of the contact structures 902 are larger than the bottom sizes of the contact structures 902, and the size difference is not less than 6 nm. The top sizes of the contact structures 902 are larger than the bottom sizes of the contact structures 902. The top sizes of the contact structures 902 are larger than the bottom sizes thereof, so that the contact structures 902 can provide a relatively large contact area, thereby further improving the yield and the performance of the semiconductor structure. After a first treatment process and a second treatment process are performed on the active pillars 20, initial contact structures 901 shown in FIG. 6A are obtained. A part of the initial contact structures 901 are removed to form the contact structures 902 shown in FIG. 6B. Outer edges of sidewalls of the contact structures 902 are arc-shaped. It may be learned from the figure that the contact structures 902 are semi-circular, and a second dielectric layer 302 is further included among the contact structures.

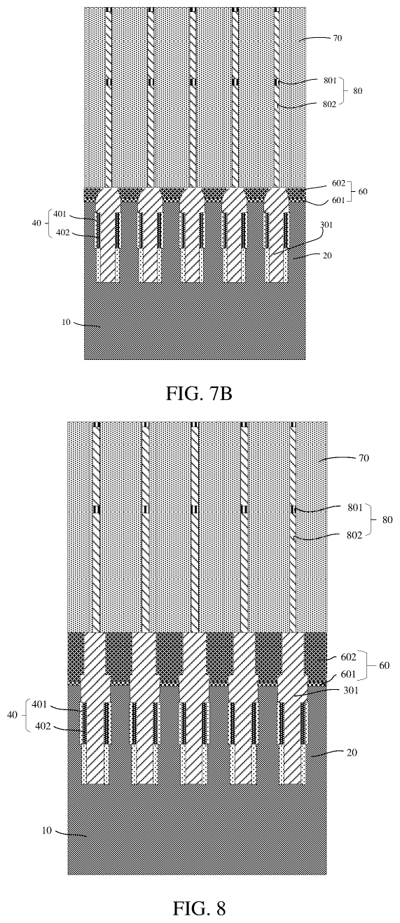

FIG. 7A is a transmission electron microscope diagram of contact structures according to a specific embodiment of the present disclosure. As shown in FIG. 7A, contact structures 60 are electrically connected to active pillars 20. Top sizes of the contact structures 60 are larger than bottom sizes of the contact structures 60. There is a size difference between the top sizes of the contact structures 60 and the bottom sizes of the contact structures 60, and the size difference is greater than 6 nm. The contact structures 60 shown in FIG. 7A are an inverted trapezoid in shape.

FIG. 7B is a schematic structural diagram of another specific implementation of a semiconductor structure according to the present disclosure. With reference to FIG. 1 and FIG. 7B, a semiconductor structure in this embodiment of the present disclosure includes a substrate 10, where the substrate 10 has active pillars 20 disposed at intervals in both a first direction X and a second direction Y, both the first direction X and the second direction Y are parallel to the surface of the substrate 10, the first direction X is perpendicular to the second direction Y, first dielectric layers 301 exist among the active pillars 20, and the first dielectric layers 301 are flush with the active pillars 20. Word line structures 40 are further included in the substrate 10, the word line structures 40 surround the active pillars 20 and extend in the first direction X, and multiple ones of the word line structures 40 are disposed at intervals in the second direction Y; and the word line structures 40 further include word line isolation layers 401 and word line metal layers 402. The semiconductor structure in the present disclosure further includes contact structures 60, and the contact structures 60 are electrically connected to the active pillars 20. The contact structures 60 include first metal layers 601 and second metal layers 602, the first metal layers 601 are electrically connected to the active pillars 20, and the second metal layers 602 are located on the first metal layers. Capacitor structures 70 are further included, and the capacitor structures 70 are electrically connected to the contact structures 60. A support structure 80 may be further included between the capacitor structures 70, and the support structure 80 includes a first support structure 801 and a second support structure 802. There is a size difference between top sizes of the contact structures 60 and bottom sizes of the contact structures 60, the top sizes of the contact structures 60 are larger than the bottom sizes of the contact structures 60, and the size difference is not less than 6 nm. The top sizes of the contact structures 60 are larger than the bottom sizes of the contact structures 60. The top sizes of the contact structures 60 are larger than the bottom sizes thereof, so that the contact structures 60 can provide a relatively large contact area, thereby further improving the yield and the performance of the semiconductor structure. Outer edges of sidewalls of the contact structures 60 are line-shaped, the sizes of the contact structures 60 from top to bottom gradually decrease, and the contact structures 60 are an inverted trapezoid in shape.

FIG. 8 is a schematic structural diagram of still another specific implementation of a semiconductor structure according to the present disclosure.

With reference to FIG. 1 and FIG. 8, a semiconductor structure in this embodiment of the present disclosure includes a substrate 10, where the substrate 10 has active pillars 20 disposed at intervals in both a first direction X and a second direction Y, both the first direction X and the second direction Y are parallel to the surface of the substrate 10, the first direction X is perpendicular to the second direction Y, first dielectric layers 301 exist among the active pillars 20, and the first dielectric layers 301 are flush with the active pillars 20. Word line structures 40 are further included in the substrate 10, the word line structures 40 surround the active pillars 20 and extend in the first direction X, and multiple ones of the word line structures 40 are disposed at intervals in the second direction Y; and the word line structures 40 further include word line isolation layers 401 and word line metal layers 402. The semiconductor structure in the present disclosure further includes contact structures 60, and the contact structures 60 are electrically connected to the active pillars 20. The contact structures 60 include first metal layers 601 and second metal layers 602, the first metal layers 601 are electrically connected to the active pillars 20, and the second metal layers 602 are located on the first metal layers. Capacitor structures 70 are further included, and the capacitor structures 70 are electrically connected to the contact structures 60. A support structure 80 may be further included between the capacitor structures 70, and the support structure 80 includes a first support structure 801 and a second support structure 802. There is a size difference between top sizes of the contact structures 60 and bottom sizes of the contact structures 60, the top sizes of the contact structures 60 are larger than the bottom sizes of the contact structures 60, and the size difference is not less than 6 nm. The top sizes of the contact structures 60 are larger than the bottom sizes of the contact structures 60. The top sizes of the contact structures 60 are larger than the bottom sizes thereof, so that the contact structures 60 can provide a relatively large contact area, thereby further improving the yield and the performance of the semiconductor structure. Outer edges of sidewalls of the contact structures are step-shaped.

A person of ordinary skill in the art may understand that the foregoing implementations are specific embodiments for implementing the present disclosure. In actual application, various modifications may be made to the forms and details of the implementations without departing from the spirit and scope of the present disclosure. Any person skilled in the art may make changes and modifications without departing from the spirit and scope of the present disclosure. Therefore, the protection scope of the present disclosure shall be subject to the scope defined by the claims.

What is claimed is:

1. A fabrication method for a semiconductor structure, comprising:
providing a substrate, the substrate having active pillars disposed at intervals in both a first direction and a second direction, both the first direction and the second direction being parallel to a surface of the substrate, the first direction being perpendicular to the second direction, first dielectric layers existing among the active pillars, and the first dielectric layers being flush with at least the active pillars;
forming word line structures, the word line structures surrounding the active pillars and extending in the first direction, and a plurality of ones of the word line structures being disposed at intervals in the second direction;
removing at least a part of the first dielectric layers to form first openings;
forming contact structures, the contact structures at least partially filling the first openings; and
forming capacitor structures, the capacitor structures being electrically connected to the contact structures.

2. The fabrication method for a semiconductor structure according to claim 1, wherein sidewalls of the first openings expose a part of the active pillars and bottoms of the first openings expose a part of the first dielectric layers.

3. The fabrication method for a semiconductor structure according to claim 2, further comprising: performing a first treatment process on the part of the active pillars exposed on the sidewalls of the first openings to expand the exposed part of the active pillars to form active pillar protrusion portions, and performing a second treatment process on the active pillar protrusion portions to form initial contact structures, wherein the initial contact structures partially fill the first openings, and a second opening is formed between adjacent ones of the initial contact structures.

4. The fabrication method for a semiconductor structure according to claim 3, further comprising: forming a second dielectric layer, wherein the second dielectric layer fills the second opening and covers the initial contact structures; removing a part of the second dielectric layer and a part of the initial contact structures, wherein a remaining part of the initial contact structures serves as the contact structures, and top sizes of the contact structures are larger than bottom sizes of the contact structures; and forming the capacitor structures on the contact structures, wherein the capacitor structures are electrically connected to the contact structures.

5. The fabrication method for a semiconductor structure according to claim 1, comprising removing a part of the first dielectric layers and a part of the active pillars to form the first openings, wherein sidewalls of the first openings expose a part of the first dielectric layers, and bottoms of the first openings expose a part of the active pillars.

6. The fabrication method for a semiconductor structure according to claim 5, wherein the forming contact structures, the contact structures at least partially filling the first openings specifically comprises: forming the contact structures, wherein the contact structures fill the first openings; the contact structures comprise first metal layers and second metal layers, and the first metal layers cover the bottoms of the first openings; and the second metal layers fill the first openings.

7. The fabrication method for a semiconductor structure according to claim 5, wherein the removing a part of the first dielectric layers and a part of the active pillars to form the first openings specifically comprises: adopting an etching gas to form the first openings by controlling an etching angle.

8. The fabrication method for a semiconductor structure according to claim 5, wherein the removing a part of the first dielectric layers and a part of the active pillars to form the first openings specifically comprises: adopting a first etching process to remove a part of the active pillars and adopting a second etching process to remove a part of the active pillars and a part of the first dielectric layers to form the first openings.

9. The fabrication method for a semiconductor structure according to claim 5, wherein the removing a part of the first dielectric layers and a part of the active pillars to form the first openings specifically comprises: forming photoresist layers on the first dielectric layers, wherein the photoresist layers have third openings, and sizes of the third openings are larger than top sizes of the active pillars; and etching the first dielectric layers with the third openings until the active pillars are exposed to form first initial openings, and continuing etching a part of the active pillars with the first initial openings to form second initial openings, wherein projections of the second initial openings on the surface of the substrate are located within projections of the first initial openings on the surface of the substrate, and the first initial openings and the second initial openings jointly constitute the first openings.

10. The fabrication method for a semiconductor structure according to claim 5, wherein there is a size difference between top sizes of the first openings and bottom sizes of the first openings, the top sizes of the first openings are larger than the bottom sizes of the first openings, and the size difference is not less than 6 nm.

11. A semiconductor structure, comprising:
a substrate, the substrate having active pillars disposed at intervals in both a first direction and a second direction, both the first direction and the second direction being parallel to a surface of the substrate, the first direction being perpendicular to the second direction, first dielectric layers existing among the active pillars, and the first dielectric layers being flush with at least the active pillars;
word line structures, the word line structures surrounding the active pillars and extending in the first direction, and a plurality of ones of the word line structures being disposed at intervals in the second direction;
contact structures, the contact structures being electrically connected to at least the active pillars; and
capacitor structures, the capacitor structures being electrically connected to the contact structures;
there being a size difference between top sizes of the contact structures and bottom sizes of the contact structures, and the top sizes of the contact structures being larger than the bottom sizes of the contact structures.

12. The semiconductor structure according to claim 11, wherein the size difference is not less than 6 nm.

13. The semiconductor structure according to claim 11, wherein the contact structures are obtained by performing a first treatment process and a second treatment process on the active pillars, and outer edges of sidewalls of the contact structures are arc-shaped.

14. The semiconductor structure according to claim 13, wherein a second dielectric layer is further comprised among the contact structures.

15. The semiconductor structure according to claim 11, wherein outer edges of sidewalls of the contact structures are line-shaped, the contact structures comprise first metal layers and second metal layers, the first metal layers are connected to the active pillars, and the second metal layers are located on the first metal layers.
